(19) United States
(12) Patent Application Publication
(10) Pub. No.: US 2024/0388372 A1
(43) Pub. Date: Nov. 21, 2024

(54) REAL-TIME CLOCK DEVICE

(71) Applicant: SEIKO EPSON CORPORATION, Tokyo (JP)

(72) Inventor: Jun Shiina, Minowa-machi (JP)

(21) Appl. No.: 18/664,838

(22) Filed: May 15, 2024

(30) Foreign Application Priority Data
May 17, 2023 (JP) 2023-081261

(51) Int. Cl. H04J 3/06; H04L 7/04

(52) U.S. Cl. CPC H04J 3/0661; H04L 7/041

(57) ABSTRACT

A real-time clock device includes: an interface circuit that receives timestamp information; an oscillation circuit that outputs an oscillation clock signal; a frequency division circuit that divides a frequency of the oscillation clock signal to generate a frequency-divided clock signal; a time counter that generates information regarding an internal time based on the frequency-divided clock signal; a phase comparator that compares phases of a reference signal and the frequency-divided clock signal and calculates a phase difference; and a processing circuit that performs processing of updating the information regarding the internal time of the time counter based on an input time indicated by the input timestamp information, and adjusts a frequency of the oscillation circuit based on a time difference between the input time and the internal time and the phase difference.

The present application is based on, and claims priority from JP Application Serial Number 2023-081261, filed May 17, 2023, the disclosure of which is hereby incorporated by reference herein in its entirety.

### BACKGROUND

### 1. Technical Field

The present disclosure relates to a real-time clock device and the like.

### 2. Related Art

Real-time clock devices that generate time information by performing time counting based on an oscillation clock signal have been known. For example, JP-A-2021-189037 discloses a method of performing subsecond correction by reading data of a subordinate subsecond counter at a timing according to a reference signal, measuring an error in time-counting data, and performing distributed theoretical regulation with a higher subsecond counter.

According to the related art disclosed in JP-A-2021-189037, it is possible to periodically correct a time with high resolution using theoretical regulation. However, with the passage of time, accuracy of a frequency of a clock signal that serves as the basis of the time-counting data decreases due to aging, which makes it difficult to provide highly accurate time unless the time information is updated frequently.

### SUMMARY

According to an aspect of the present disclosure, a real-time clock device includes: an interface circuit that receives timestamp information; an oscillation circuit that outputs an oscillation clock signal; a frequency division circuit that divides a frequency of the oscillation clock signal to generate a frequency-divided clock signal; a time counter that generates information regarding an internal time based on the frequency-divided clock signal; a phase comparator that compares phases of a reference signal and the frequency-divided clock signal and calculates a phase difference between the reference signal and the frequency-divided clock signal; and a processing circuit that performs processing of updating the information regarding the internal time of the time counter based on an input time indicated by the input timestamp information, and adjusts a frequency of the oscillation circuit based on a time difference between the input time and the internal time and the phase difference.

### BRIEF DESCRIPTION OF THE DRAWINGS

FIG. 1 illustrates a configuration example of a real-time clock device according to the present embodiment.

FIG. 2 is an explanatory diagram illustrating problems of a method according to a comparative example.

FIG. 3 is an explanatory diagram illustrating a method according to the present embodiment.

FIG. 4 is an explanatory diagram illustrating input and output signals according to the present embodiment.

FIG. 5 illustrates a detailed configuration example of the real-time clock device according to the present embodiment.

FIG. 6 is a signal waveform diagram illustrating an operation according to the present embodiment.

FIG. 7 is a flowchart for describing the operation according to the present embodiment.

FIG. 8 is an explanatory diagram illustrating an example of a signal waveform of communication performed by an interface circuit.

FIG. 9 is an explanatory diagram illustrating an example of a reference signal generation method.

FIG. 10 is an explanatory diagram illustrating an example of the reference signal generation method.

FIG. 11 illustrates a detailed configuration example of the real-time clock device according to the present embodiment.

FIG. 12 is a signal waveform diagram illustrating an operation according to the present embodiment.

FIG. 13 is a flowchart for describing the operation according to the present embodiment.

### DESCRIPTION OF EMBODIMENTS

Hereinafter, the present embodiment will be described. Note that the present embodiment described below does not unduly limit the contents described in the claims. Furthermore, not all of the configurations described in the present embodiment are essential configuration requirements.

### 1. Real-Time Clock Device

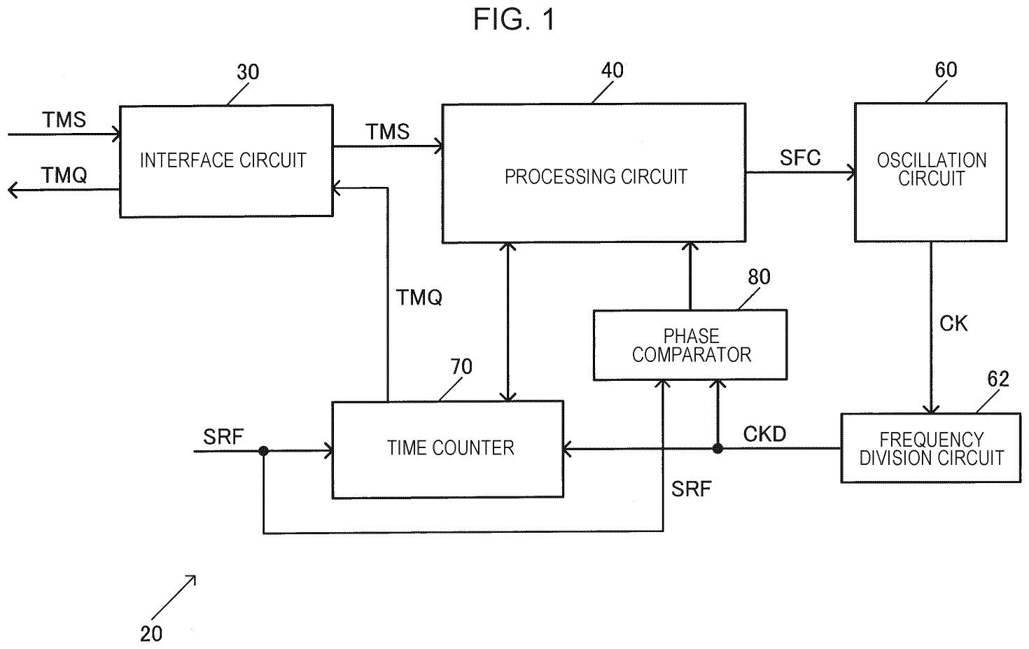

FIG. 1 illustrates a configuration example of a real-time clock device 20 according to the present embodiment. The real-time clock device 20 is a device that generates time information by performing time counting based on, for example, an oscillation clock signal CK, and is, for example, a real-time clock module. The real-time clock device 20 of FIG. 1 includes an interface circuit 30, a processing circuit 40, an oscillation circuit 60, a frequency division circuit 62, a time counter 70, and a phase comparator 80. The real-time clock device 20 is not limited to the configuration illustrated in FIG. 1, and various modifications such as omission of some components, addition of other components, and replacement of some components with other components are possible.

The interface circuit 30 is a circuit for communicating with an external processing device. For example, the interface circuit 30 performs communication based on a given communication standard with an external processing device. For example, the interface circuit 30 performs serial communication such as inter-integrated circuit (I2C) or serial peripheral interface (SPI). In a case of the serial communication, the real-time clock device 20 includes communication terminals such as a serial clock input terminal and a serial data input/output terminal. In FIG. 1, timestamp information TMS, which is time information, is input to the interface circuit 30. For example, the timestamp information TMS is input as serial data to the interface circuit 30.

The processing circuit 40 is a circuit that performs various arithmetic processing, control processing, or the like in the real-time clock device 20. The processing circuit 40 can be implemented, for example, by a logic circuit, and specifically, by an application-specific integrated circuit (ASIC) or the like implemented using automatic placement and routing of a gate array or the like.

The oscillation circuit 60 is a circuit that outputs the oscillation clock signal CK. For example, the oscillation circuit 60 generates an oscillation signal through an oscillation operation, and outputs the oscillation clock signal CK based on the oscillation signal. For example, the oscillation circuit 60 generates an oscillation signal with a frequency controlled by a frequency control signal SFC from the processing circuit 40, and outputs the oscillation clock signal CK based on the oscillation signal. As an example, the oscillation circuit 60 generates a sine wave oscillation signal by driving and oscillating a resonator such as a quartz crystal resonator with a drive circuit, and shapes a waveform of the generated oscillation signal with a waveform shaping circuit to output the square wave oscillation clock signal CK. The oscillation clock signal CK is, for example, a clock signal with a frequency of 32.768 KHz. The frequency of the oscillation clock signal CK is not limited thereto, and may be a frequency of 32 KHz or the like. The real-time clock device 20 may include a clock output terminal that outputs the oscillation clock signal CK. The oscillation operation of the oscillation circuit 60 is not limited to using such a resonator, and various modifications are possible.

The frequency division circuit 62 divides the frequency of the oscillation clock signal CK from the oscillation circuit 60 to generate a frequency-divided clock signal CKD. For example, the frequency division circuit 62 includes a frequency division counter that operates based on the oscillation clock signal CK, and uses the frequency division counter to generate the frequency-divided clock signal CKD. The frequency-divided clock signal CKD is, for example, a clock signal with a frequency of 1 Hz. The frequency division circuit 62 can include a first frequency division circuit and a second frequency division circuit. The first frequency division circuit divides the frequency of the oscillation clock signal CK by a first frequency division ratio, and the second frequency division circuit divides a first frequency-divided clock signal from the first frequency division circuit by a second frequency division ratio and outputs the frequency-divided clock signal CKD, which is a second frequency-divided clock signal. The first frequency division ratio is, for example, 32, and a frequency of the first frequency-divided clock signal is, for example, 1.024 KHz. The second frequency division ratio is, for example, 1024, and thus, the frequency-divided clock signal CKD of 1 Hz is output from the frequency division circuit 62. Any one of the oscillation clock signal CK, the first frequency-divided clock signal, and the frequency-divided clock signal CKD, which is the second frequency-divided clock signal, may be selected and output from the clock output terminal of the real-time clock device 20.

The time counter 70 performs time counting processing based on the frequency-divided clock signal CKD from the frequency division circuit 62. The time counter 70, which is a time counting circuit, generates, for example, time information TMQ indicating the current time through the time counting processing. The time information TMQ, which is time-counting data, can include data indicating seconds, minutes, hours, days, months, years, and the like. For example, the time counter 70 includes respective counters for counting seconds, minutes, hours, days, months, and years, and generates the time information TMQ through counting processing performed by the counters. The generated time information TMQ is output as output timestamp information to the outside via the interface circuit 30. Further, information regarding an internal time corresponding to the time information TMQ is output from the time counter 70 to the processing circuit 40.

The phase comparator 80 compares phases of the frequency-divided clock signal CKD from the frequency division circuit 62 and a reference signal SRF, and outputs a phase comparison result. The phase comparator 80 compares, for example, an edge timing of the frequency-divided clock signal CKD and an edge timing of the reference signal SRF, calculates a phase difference between the edge timings, and outputs information regarding the phase difference as the phase comparison result. The phase difference is information indicating the phase difference between the frequency-divided clock signal CKD and the reference signal SRF, and is, for example, digital data indicating the phase difference. The reference signal SRF is, for example, a signal for synchronization of the timestamp information TMS input to the real-time clock device 20, and is a reference synchronization signal. For example, a time indicated by the timestamp information TMS is a time at the edge timing of the reference signal SRF. The edge timing is, for example, a rising edge or a falling edge of a signal. For example, a processing device such as an external microcomputer outputs time information indicating the time at the edge timing of the reference signal SRF as the timestamp information TMS, and the timestamp information TMS is input to the interface circuit 30. For example, a 1PPS signal of a global positioning system (GPS) can be used as the reference signal SRF, but the reference signal SRF is not limited thereto. For example, when time information is transmitted to synchronize a plurality of communication devices connected via a network, a synchronization signal of the time information may be used as the reference signal SRF.

As described above, the real-time clock device 20 according to the present embodiment includes the interface circuit 30 to which the timestamp information TMS is input, the oscillation circuit 60 that outputs the oscillation clock signal CK, the frequency division circuit 62 that divides the frequency of the oscillation clock signal CK to generate the frequency-divided clock signal CKD, and the time counter 70 that generates the information regarding the internal time based on the frequency-divided clock signal CKD. The real-time clock device 20 further includes the phase comparator 80 that compares the phases of the reference signal SRF for synchronization of the timestamp information TMS and the frequency-divided clock signal CKD, and calculates the phase difference between the reference signal SRF and the frequency-divided clock signal CKD, and the processing circuit 40. For example, the phase comparator 80 outputs, to the processing circuit 40, the information regarding the phase difference between the edge timings of the reference signal SRF and the frequency-divided clock signal CKD. The processing circuit 40 performs processing of updating the internal time of the time counter 70 based on an input time indicated by the input timestamp information TMS. That is, the processing circuit 40 updates the information regarding the internal time of the time counter 70 based on the input time indicated by the timestamp information TMS input from the outside via the interface circuit 30. For example, the processing circuit 40 performs update processing of setting the internal time of the time counter 70 to the input time indicated by the timestamp information TMS. Furthermore, the processing circuit 40 adjusts a frequency of the oscillation circuit 60 based on a time difference between the input time and the internal time and the phase difference between the reference signal SRF and the frequency-divided clock signal CKD. For example, the processing circuit 40 computes the time difference between the input time indicated by the timestamp information TMS and the internal time, and acquires information regarding the phase difference between the reference signal SRF and the frequency-divided clock signal CKD from the phase comparator 80. The processing circuit 40 then adjusts an oscillation frequency of the oscillation circuit 60 to a frequency that brings the time difference between the internal time and the input time close to zero and also brings the phase difference close to zero. For example, the processing circuit 40 adjusts the oscillation frequency of the oscillation circuit 60 by computing a frequency offset based on the time difference and the phase difference and outputting the frequency control signal SFC corresponding to the frequency offset.

As described above, according to the present embodiment, the time counter 70 performs time counting processing based on the frequency-divided clock signal CKD of the oscillation clock signal CK, thereby making it possible to generate the information regarding the internal time as the time information. Then, the information regarding the internal time of the time counter 70 is updated based on the input time indicated by the input timestamp information TMS, so that the internal time can be corrected to the input time. Furthermore, in the present embodiment, the frequency of the oscillation circuit 60 is adjusted based on the time difference between the input time and the internal time and the phase difference between the reference signal SRF and the frequency-divided clock signal CKD. Accordingly, it is possible to adjust the frequency of the oscillation circuit 60 based on the phase difference between the reference signal SRF and the frequency-divided clock signal CKD in addition to the time difference between the input time and the internal time. For example, it is possible to perform frequency adjustment in such a way as to decrease the time difference between the input time and the internal time and decrease the phase difference between the reference signal SRF and the frequency-divided clock signal CKD. As a result, it is possible to implement the real-time clock device 20 that can suppress a time counting error caused by an oscillation frequency deviation and provide highly accurate time information even when a deviation occurs in the oscillation frequency due to aging, for example.

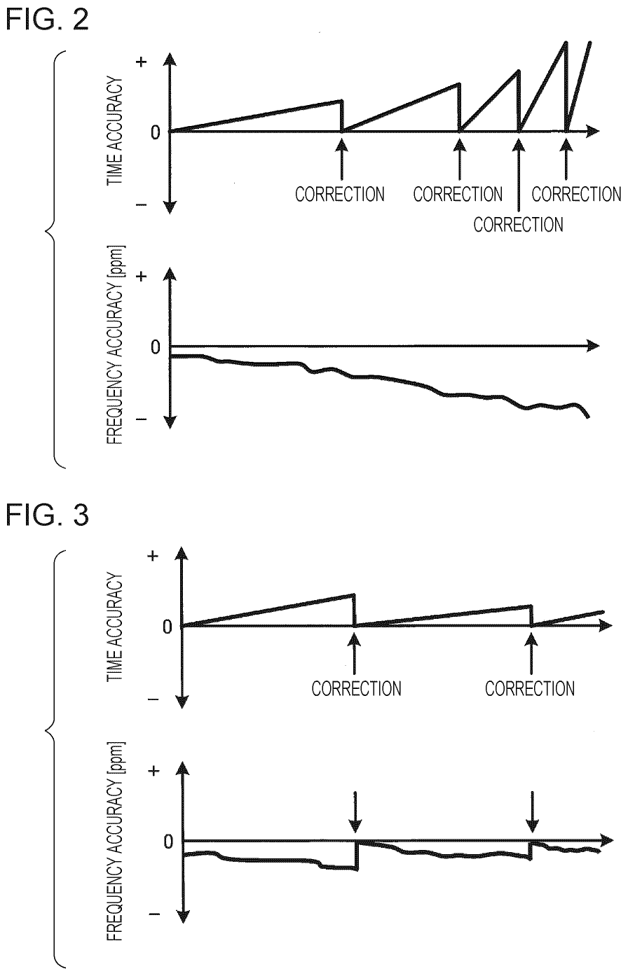

For example, FIG. 2 is an explanatory diagram illustrating problems of a method according to a comparative example for the present embodiment. In FIG. 2, a frequency error corresponding to oscillation frequency accuracy increases over time due to aging or the like, and the frequency error causes an internal time deviation. Then, correction is performed to eliminate the internal time deviation caused by such a frequency error. In this case, since the frequency error increases over time, the internal time deviation also increases, frequent internal time correction becomes necessary. For example, in a packaged real-time clock (RTC) module according to the related art, a frequency offset increases over time due to aging of a resonator, which is an internal oscillation element, leading to an accelerated time deviation. In order to maintain highly accurate time information when there is a large time deviation, it is necessary to frequently update the time information as illustrated in FIG. 2, making it difficult to provide highly accurate time information. Meanwhile, a method can also be considered in which a reference signal is input to a real-time clock module, and theoretical regulation correction for time counting is performed in order to achieve high-accuracy time. In this case, it is necessary to input the reference signal separately from the time information. Furthermore, since frequency adjustment is not performed in the theoretical regulation, when a clock signal is output from the real-time clock module, clock accuracy remains poor. In addition, a method can also be considered in which frequency adjustment of a clock generation circuit is performed by a processing device such as an MCU without using a packaged real-time clock module in order to achieve an accurate time-counting clock. However, with such a method, a device size and power consumption become larger than those in a case of using a packaged real-time clock module. Furthermore, since the frequency adjustment is performed only by time comparison, there is a problem in that the frequency adjustment can only be performed up to a time resolution of timestamps.

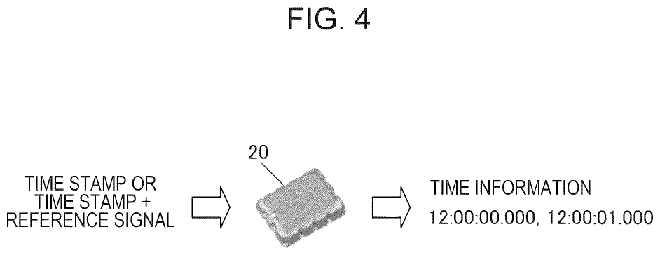

In this regard, in the present embodiment, the oscillation frequency is adjusted using the phase difference between the reference signal SRF and the frequency-divided clock signal CKD in addition to the time difference between the input time indicated by the timestamp information TMS and the internal time. Therefore, correction for updating the internal time to the input time is performed, and correction for bringing the frequency error close to zero is also performed as illustrated in FIG. 3. Accordingly, it is possible to provide the real-time clock device 20 that can provide accurate time information and maintain time accuracy. In the present embodiment, the oscillation frequency can be adjusted based on the time difference and the phase difference by inputting the timestamp information TMS, or the timestamp information TMS and the reference signal SRF to the real-time clock device 20 as illustrated in FIG. 4. Therefore, the real-time clock device 20, which is a packaged real-time clock module, has a built-in correction function for adjusting the oscillation frequency based on the time difference and the phase difference, thereby making it possible to provide highly accurate time information with a small size and low power consumption.

### 2. Detailed Configuration Example

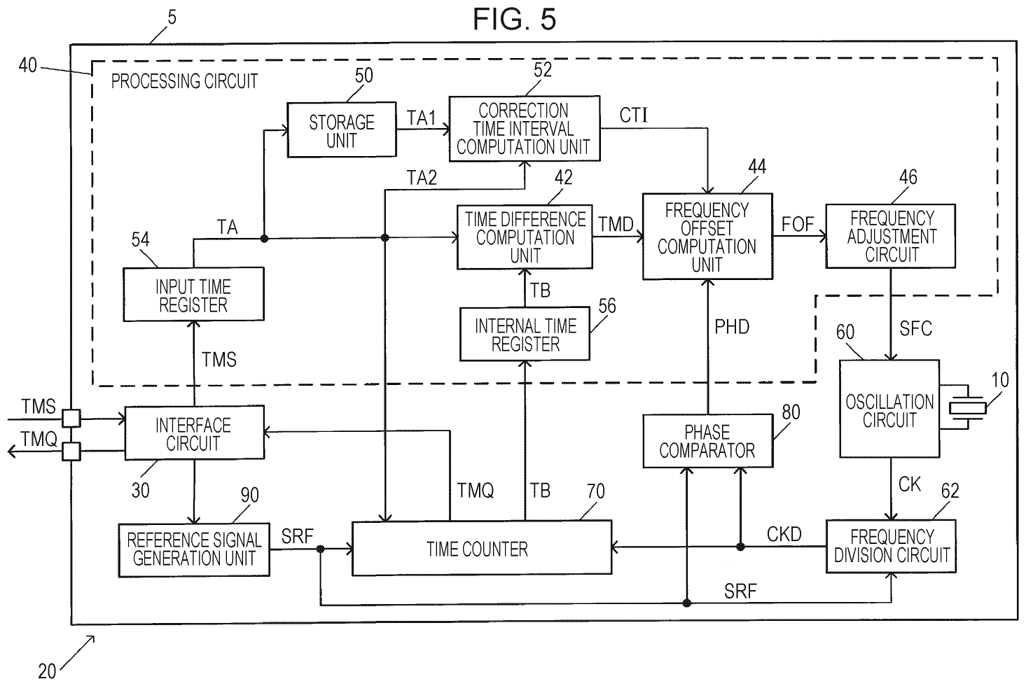

FIG. 5 illustrates a detailed configuration example of the real-time clock device 20 according to the present embodiment. The real-time clock device 20 of FIG. 5 includes a reference signal generation unit 90 in addition to the interface circuit 30, the processing circuit 40, the oscillation circuit 60, the frequency division circuit 62, the time counter 70, and the phase comparator 80. The reference signal generation unit 90 generates the reference signal SRF based on the timestamp information TMS. The real-time clock device 20 and the processing circuit 40 are not limited to the configuration illustrated in FIG. 5, and various modifications such as omission of some components, addition of other components, and replacement of some components with other components are possible.

In FIG. 5, the oscillation circuit 60 generates the oscillation signal by causing a resonator 10 to oscillate, and outputs the oscillation clock signal CK. The resonator 10 is an element that generates mechanical resonances based on an electrical signal. The resonator 10 can be implemented by, for example, a resonator element such as a quartz crystal resonator element. For example, the resonator 10 can be implemented by a quartz crystal resonator element that has a cut angle of AT cut, SC cut, or the like and that performs thickness-shear oscillation, a tuning fork type quartz crystal resonator element, or a double tuning fork type quartz crystal resonator element. The resonator 10 according to the present embodiment can also be implemented by various types of resonator elements such as a resonator element other than the thickness-shear oscillation type, the tuning fork type, or the double tuning fork type, and a piezoelectric resonator element formed of a material other than quartz crystal. For example, a surface acoustic wave (SAW) resonator, a micro electro mechanical systems (MEMS) resonator as a silicon resonator formed using a silicon substrate, or the like can be employed as the resonator 10.

For example, in the real-time clock device 20 of FIG. 5, an integrated circuit device including the interface circuit 30, the processing circuit 40, the oscillation circuit 60, the frequency division circuit 62, the time counter 70, the phase comparator 80, and the like, and the resonator 10 are housed in a package 5. The integrated circuit device is a circuit device called an integrated circuit (IC). For example, the integrated circuit device is an IC manufactured by a semiconductor process, and is a semiconductor chip in which circuit elements are formed on a semiconductor substrate. The resonator 10 is electrically coupled to the integrated circuit device. For example, the resonator 10 and the integrated circuit device are electrically coupled to each other using internal wiring of the package 5 that houses the resonator 10 and the integrated circuit device, bonding wires, metal bumps, or the like. It is also possible to implement a modification in which the resonator 10 is not built in the real-time clock device 20 but is provided externally.

The oscillation circuit 60 can be implemented by, for example, an oscillation drive circuit electrically coupled to one end and the other end of the resonator 10, and passive elements such as a capacitor and a resistor. The drive circuit can be implemented by, for example, a bipolar transistor or a CMOS inverter circuit. The drive circuit is a core circuit of the oscillation circuit 60 and applies a voltage or current to the resonator 10 to oscillate the resonator 10. Various types of oscillation circuits such as an inverter oscillation circuit, a pierce oscillation circuit, a Colpitts oscillation circuit, and a Hartley oscillation circuit can be used as the oscillation circuit 60.

Further, the oscillation circuit 60 can include a variable capacitance circuit (not illustrated). The variable capacitance circuit includes, for example, a capacitor array including a plurality of capacitors and a switch array including a plurality of switches. Each capacitor of the plurality of capacitors and each switch of the plurality of switches are coupled in series between a node at one end or the other end of the resonator 10 and, for example, a ground node. Further, capacitance values of the plurality of capacitors in the capacitor array are binary weighted. The plurality of switches in the switch array are turned on and off based on frequency control data, which is the frequency control signal SFC from the processing circuit 40. As a result, a capacitance value of the variable capacitance circuit is controlled, and the oscillation frequency of the oscillation circuit 60 is adjusted. Alternatively, the variable capacitance circuit may be implemented by a variable capacitance element such as a varactor. In this case, a frequency control voltage is input to the oscillation circuit 60 as the frequency control signal SFC from the processing circuit 40, and the capacitance of the variable capacitance element is adjusted by the frequency control voltage, as a result of which the oscillation frequency of the oscillation circuit 60 is adjusted. Further, in the present embodiment, a temperature compensation circuit that performs temperature compensation processing based on a temperature detection signal from a temperature sensor may be provided. In this case, temperature compensation of the oscillation frequency is performed by adjusting the capacitance of the variable capacitance circuit based on a temperature compensation result of the temperature compensation circuit. Note that the coupling in the present embodiment is electrical coupling. The electrical coupling is coupling that allows transmission of electrical signals, and is coupling that allows transmission of information by electrical signals. The electrical coupling may be made via a passive element or the like.

In FIG. 5, the processing circuit 40 includes a time difference computation unit 42, a frequency offset computation unit 44, and a frequency adjustment circuit 46. The time difference computation unit 42 calculates a time difference TMD between an input time TA and an internal time TB set in the time counter 70. For example, information regarding the input time TA indicated by the timestamp information TMS input via the interface circuit 30 is stored in an input time register 54. Further, information regarding the internal time TB generated by the time counting processing in the time counter 70 is stored in an internal time register 56. Then, the time difference computation unit 42 calculates the time difference TMD between the input time TA from the input time register 54 and the internal time TB from the internal time register 56.

The reference signal generation unit 90 generates the reference signal SRF based on the timestamp information TMS. For example, when the timestamp information TMS is input from the outside via the interface circuit 30, the reference signal generation unit 90 generates the reference signal SRF, which is a signal of a reference timing of a timestamp, from the timestamp information TMS. At the same time, the input time TA indicated by the timestamp information TMS is stored in the input time register 54. Further, the phase comparator 80 calculates a phase difference PHD between the reference signal SRF generated by the reference signal generation unit 90 and the frequency-divided clock signal CKD from the frequency division circuit 62. Then, the frequency offset computation unit 44 calculates a frequency offset FOF based on the time difference TMD from the time difference computation unit 42 and the phase difference PHD from the phase comparator 80. For example, the frequency offset computation unit 44 calculates, as the frequency offset FOF, an average offset frequency deviation based on a result of adding the time difference TMD and the phase difference PHD. Then, the frequency adjustment circuit 46 adjusts the frequency of the oscillation circuit 60 based on the frequency offset FOF. For example, the frequency adjustment circuit 46 generates the frequency control signal SFC that increases or decreases the frequency of the oscillation clock signal CK by the calculated frequency offset FOF, and outputs the generated frequency control signal SFC to the oscillation circuit 60. The oscillation circuit 60 outputs the oscillation clock signal CK with the oscillation frequency according to the frequency offset FOF. For example, the capacitance of the variable capacitance circuit of the oscillation circuit 60 is controlled according to the frequency control signal SFC based on the frequency offset FOF, so that the oscillation clock signal CK with oscillation frequency according to the frequency offset FOF is generated.

As described above, in the present embodiment, the time difference computation unit 42 calculates the time difference TMD between the input time TA and the internal time TB, the frequency offset computation unit 44 calculates the frequency offset FOF based on the time difference TMD and the phase difference PHD, and the frequency adjustment circuit 46 adjusts the frequency of the oscillation circuit 60 based on the frequency offset FOF. As a result, it is possible to adjust the frequency of the oscillation circuit 60 by calculating the frequency offset FOF that also reflects the phase difference PHD between the reference signal SRF and the frequency-divided clock signal CKD in addition to the time difference TMD between the input time TA indicated by the timestamp information TMS and the internal time TB set in the time counter 70.

Further, in the present embodiment, the processing circuit 40 calculates a correction time interval CTI based on a first input time TA1 indicated by the timestamp information TMS that is input at a first timing, and a second input time TA2 indicated by the timestamp information TMS that is input at a second timing after the first timing. For example, a time difference between the first input time TA1 indicated by the timestamp information TMS input via the interface circuit 30 at the first timing, and the second input time TA2 indicated by the timestamp information TMS that is input via the interface circuit 30 at the next second timing is calculated, and the correction time interval CTI is set based on the time difference. Then, the frequency of the oscillation circuit 60 is adjusted based on the correction time interval CTI, the time difference TMD between the input time and the internal time, and the phase difference PHD between the reference signal SRF and the frequency-divided clock signal CKD. For example, the frequency of the oscillation circuit 60 is adjusted based on a value obtained by dividing the result of adding the time difference TMD and the phase difference PHD by the correction time interval CTI. As a result, it is possible to implement, even when the correction interval based on the timestamp information TMS is not constant, appropriate frequency adjustment of the oscillation circuit 60 based on the time difference TMD and the phase difference PHD by calculating the correction time interval CTI based on the difference between the first input time TA1 at the first timing and the second input time TA2 at the second timing.

Specifically, as illustrated in FIG. 5, the processing circuit 40 includes a storage unit 50, a correction time interval computation unit 52, the time difference computation unit 42, the frequency offset computation unit 44, and the frequency adjustment circuit 46. The storage unit 50 stores the first input time TA1 indicated by the timestamp information TMS that is input at the first timing. The correction time interval computation unit 52 calculates the correction time interval CTI based on the first input time TA1 stored in the storage unit 50 and the second input time TA2 indicated by the timestamp information TMS at the second timing. For example, the first input time TA1 indicated by the timestamp information TMS that is input via the interface circuit 30 at the first timing is set in the input time register 54 and stored in the storage unit 50. Further, the second input time TA2 indicated by the timestamp information TMS that is input via the interface circuit 30 at the next second timing is set in the input time register 54 and input to the correction time interval computation unit 52. Then, the correction time interval computation unit 52 calculates the correction time interval CTI based on the first input time TA1 from the storage unit 50 and the second input time TA2 from the input time register 54. For example, the correction time interval is calculated as CTI=TA2−TA1. Further, the time difference computation unit 42 calculates the time difference TMD between the second input time TA2 and the internal time TB. For example, the time difference computation unit 42 calculates the time difference TMD between the second input time TA2 set in the input time register 54 and the internal time TB set in the internal time register 56 from the time counter 70. That is, the time difference TMD occurring during the correction time interval CTI is calculated. The frequency offset computation unit 44 then performs computation to estimate the frequency offset FOF based on the correction time interval CTI, the time difference TMD, and the phase difference PHD. For example, the frequency offset computation unit 44 calculates the frequency offset, which is the average offset frequency deviation, as FOF=(TMD+PHD)/CTI. Then, the frequency adjustment circuit 46 adjusts the frequency of the oscillation circuit 60 based on the frequency offset FOF. For example, frequency correction is performed in the frequency adjustment circuit 46 in such a way as to cancel the estimated frequency offset FOF.

As described above, in the present embodiment, the correction time interval computation unit 52 calculates the correction time interval CTI based on the first input time TA1 at the first timing and the second input time TA2 at the next second timing. Further, the time difference computation unit 42 calculates the time difference TMD between the second input time TA2 and the internal time TB. Then, the frequency offset computation unit 44 calculates the frequency offset FOF based on the correction time interval CTI, the phase difference PHD, and the time difference TMD, and the frequency adjustment circuit 46 adjusts the frequency of the oscillation circuit 60 based on the frequency offset FOF. As a result, even when the correction interval based on the timestamp information TMS is not constant, the correction time interval computation unit 52 calculates the correction time interval CTI based on the first input time TA1 and the second input time TA2, so that it is possible to implement appropriate frequency adjustment of the oscillation circuit 60 based on the time difference TMD and phase difference PHD.

Although FIG. 5 illustrates a configuration in which the correction time interval computation unit 52 calculates the correction time interval CTI, the present embodiment is not limited thereto. For example, when the correction time interval CTI is known, the correction time interval computation unit 52, the storage unit 50, and the like do not have to be provided. For example, when the timestamp information TMS is input at constant time intervals, the correction time interval CTI is a known interval, and thus, a modification in which the correction time interval computation unit 52 and the storage unit 50 are not provided is possible.

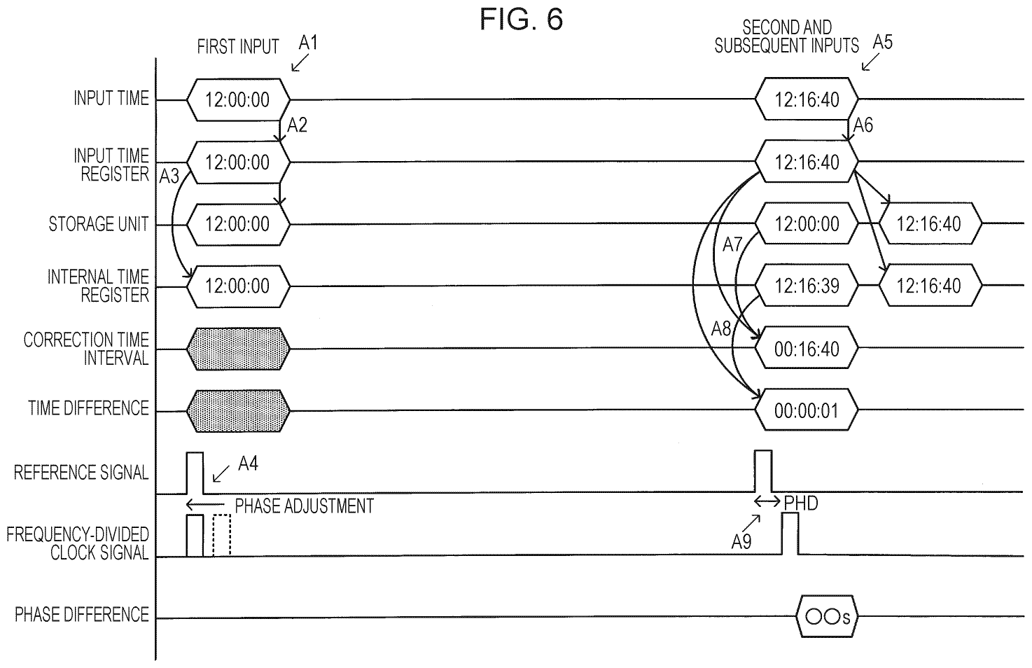

FIG. 6 is a signal waveform diagram illustrating an operation of the configuration example of FIG. 5. At the first input indicated by A1 of FIG. 6, the input time TA (TA=TA1=[12:00:00]) is input by the timestamp information TMS. Then, the input time TA (TA=TA1=[12:00:00]) is set in the input time register 54 as indicated by A2. TA1 indicates the first input time. The reference signal generation unit 90 generates the reference signal SRF based on the timestamp information TMS. Then, the information regarding the internal time TB of the time counter 70 is updated with the reference signal SRF as a trigger, and the updated internal time TB (TB=[12:00:00]) is set in the internal time register 56 as indicated by A3. Further, adjustment processing is performed to align a time-counting timing with a timing of the reference signal SRF as indicated by A4. Specifically, phase adjustment processing is performed to align the edge timing of the frequency-divided clock signal CKD with the edge timing of the reference signal SRF. The phase adjustment processing can be implemented, for example, by resetting or setting the frequency division counter of the frequency division circuit 62 based on the reference signal SRF.

Further, at the second input, the input time TA (TA=TA2=[12:16:40]) is input as indicated by A5 of FIG. 6. For example, when a timing of the first input is the first timing, a timing of the second input is the second timing. Similarly, when the timing of the second input is the first timing, a timing of the third input is the second timing. The same applies to the following. Then, the input time TA (TA=TA2=[12:16:40]) is set in the input time register 54 as indicated by A6. TA2 indicates the second input time. Further, a duration of 16 minutes and 40 seconds, which is a time difference between the input time TA (TA=TA2=[12:16:40]) and the input time TA (TA=TA1=[12:00:00]) stored in the storage unit 50, is obtained as the correction time interval CTI as indicated by A7. A duration of 1 second is obtained as the time difference TMD between the input time TA (TA=TA2=[12:16:40]) and the internal time TB (TB=[12:16:39]) (TMD=1 second) as indicated by A8. That is, here, the internal time lags behind the input time, which is the actual time, due to aging of the oscillation frequency of the resonator 10, for example, and a duration of 1 second is obtained as the time difference TMD (TMD=1 second). When the internal time is ahead of the input time, the time difference TMD has a negative value. Furthermore, the phase difference PHD between the reference signal SRF and the frequency-divided clock signal CKD is also calculated as indicated by A9. For example, the edge timings of the reference signal SRF and the frequency-divided clock signal CKD are the same as each other at A4, but the edge timing of the frequency-divided clock signal CKD lags behind the edge timing of the reference signal SRF at A9, and such a difference is obtained as the phase difference PHD. Then, the frequency offset FOF is calculated based on the time difference TMD and the phase difference PHD, and frequency adjustment of the oscillation circuit 60 is performed based on the frequency offset FOF. For example, when the time difference TMD is 1 second and the phase difference PHD is 0.1 seconds, TMD+PHD=1.1 seconds. In this case, (TMD+PHD)/CTI=1.1 seconds/16 minutes and 40 seconds is obtained as the average offset frequency deviation, and the frequency offset of the oscillation circuit 60 is corrected.

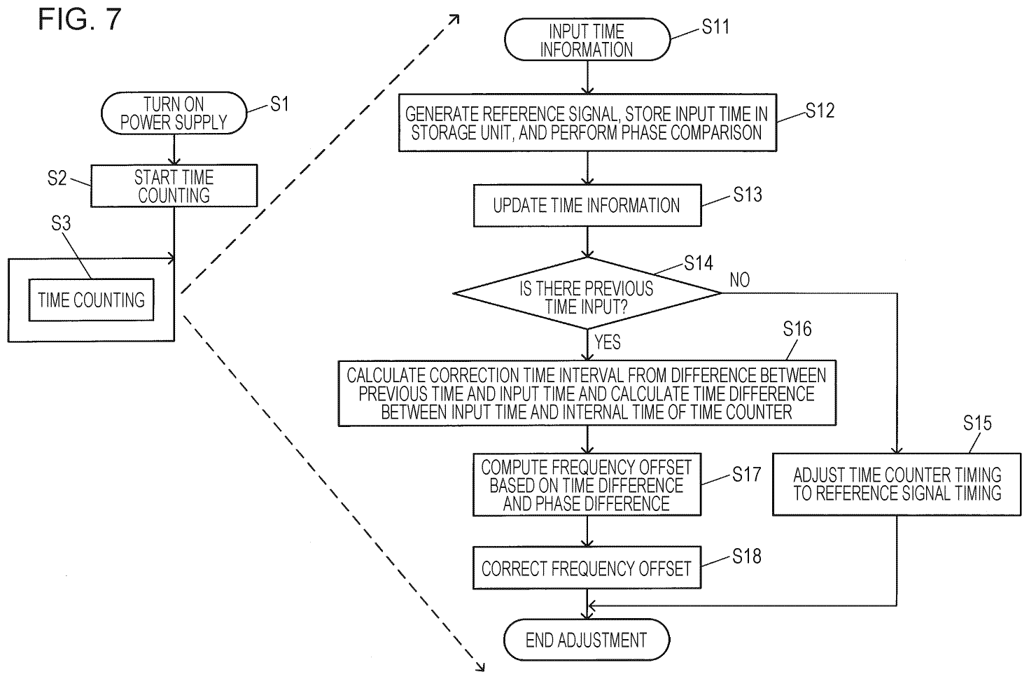

FIG. 7 is a flowchart for describing the operation of the configuration example of FIG. 5. When a power supply is turned on and the real-time clock device 20 is activated (step S1), time counting by the time counter 70 is started and performed (steps S2 and S3). As described with reference to FIGS. 6 and 3, when the time information is input to the real-time clock device 20 using the timestamp information TMS (step S11), the reference signal SRF is generated, the input time is stored in the storage unit 50, and phase comparison between the reference signal SRF and the frequency-divided clock signal CKD is performed (step S12). Then, the time information of the time counter 70 and the like is updated (step S13). At the first input indicated by A1 in FIG. 6, the phase comparison in step S12 is not performed.

When the input is the first input and there is no previous time input, processing of adjusting the time-counting timing to the timing of the reference signal SRF is performed (steps S14 and S15). That is, the phase adjustment processing is performed to align the edge timing of the frequency-divided clock signal CKD with the edge timing of the reference signal SRF as indicated by A4 of FIG. 6. On the other hand, when there is a previous time input, the correction time interval CTI is calculated from the difference between a previous time and the input time, and the time difference TMD between the input time and the internal time of the time counter 70 is calculated (step S14 and S16). Then, the frequency offset FOF is calculated from the time difference TMD and the phase difference PHD calculated in step S12 (step S17), and frequency offset correction is performed (step S18).

As described above, in the present embodiment, the frequency offset correction for the oscillation circuit 60 is performed based on the time difference TMD between the input time and the internal time and the phase difference PHD between the reference signal SRF and the frequency-divided clock signal CKD, so that it is possible to provide accurate time information and maintain time accuracy. In addition, since the frequency offset FOF is calculated using the correction time interval CTI that is the difference between the previous time and the input time, it is possible to implement appropriate frequency offset correction based on the time difference TMD and the phase difference PHD by using the correction time interval CTI even when the correction interval is not constant.

Further, in FIG. 5, the real-time clock device 20 includes the reference signal generation unit 90 that generates the reference signal SRF based on the timestamp information TMS. As a result, the reference signal SRF can be generated based on the timestamp information TMS without inputting the reference signal SRF for synchronization of the timestamp information TMS from the outside, so that it is possible to adjust the frequency of the oscillation circuit 60 by calculating the phase difference PHD between the reference signal SRF and the frequency-divided clock signal CKD. Furthermore, for example, it is possible to update the internal time of the time counter 70 based on the reference signal SRF generated by the reference signal generation unit 90, and it is possible to update the internal time at an appropriate timing.

Specifically, in the present embodiment, the reference signal generation unit 90 generates the reference signal SRF based on an input timing or an input end timing of the timestamp information TMS. As a result, the timing of the reference signal SRF can be set by effectively utilizing the input timing or the input end timing of the timestamp information TMS. Then, it is possible to perform phase comparison between the reference signal SRF whose timing is set as described above and the frequency-divided clock signal CKD.

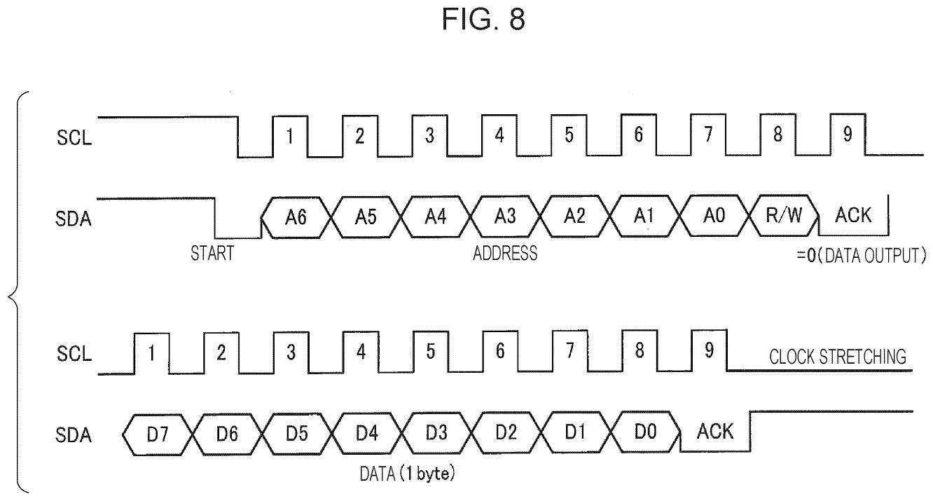

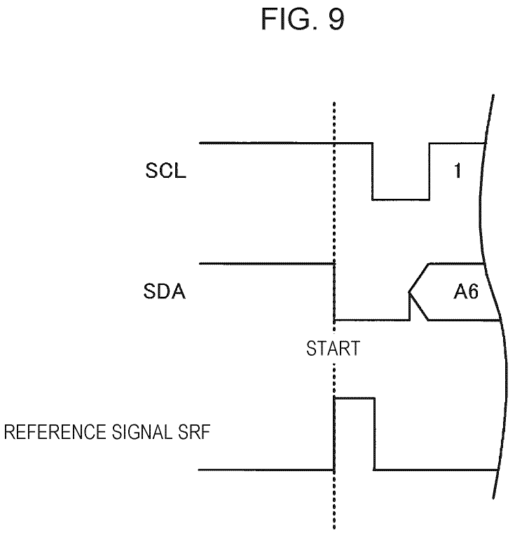

For example, FIG. 8 illustrates an example of a signal waveform when the interface circuit 30 performs I2C serial communication. I2C is a synchronous serial communication method in which communication is performed using two signal lines, a serial clock signal SCL and a serial data signal SDA. A plurality of slaves can be connected to an I2C bus, and a master specifies an individually determined slave address, selects a slave, and then communicates with the slave. In I2C, after a start condition in which the master sets the serial data signal SDA to a low level, an address is communicated in synchronization with the serial clock signal SCL, and then data is communicated in synchronization with the serial clock signal SCL. When the data communication is completed, an ACK bit is returned, and clock stretching is done. In the present embodiment, the reference signal SRF is generated based on the input timing of the timestamp information TMS. Specifically, as illustrated in FIG. 9, the reference signal generation unit 90 generates the reference signal SRF at a timing of the start condition of I2C. For example, the reference signal generation unit 90 changes the reference signal SRF from a low level to a high level, which is an active level, at a timing at which the serial data signal SDA changes to a low level. As a result, the reference signal SRF can be generated using an input timing of I2C at which the serial data signal SDA changes from a high level to a low level.

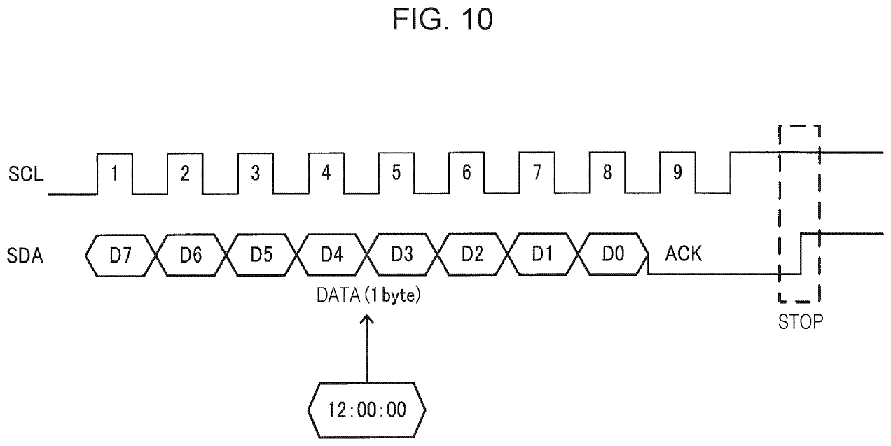

In the present embodiment, the reference signal generation unit 90 may generate the reference signal SRF based on the input end timing. For example, in FIG. 10, the master outputs a stop condition by setting the serial data signal SDA to a high level after ACK. In this case, the reference signal generation unit 90 may set the timing of the reference signal SRF by using, for example, a timing of the stop condition of I2C. For example, after completion of data reception according to the stop condition, a time required for the data reception is determined from the amount of input data, and phase comparison with the frequency-divided clock signal CKD is performed at a timing shifted by the determined time.

The generation of the reference signal SRF is not limited to the methods described in FIGS. 8 to 10. For example, various modifications such as generating the reference signal SRF based on the first change timing of a serial clock signal after slave selection in the SPI are possible.

### 3. Another Detailed Configuration Example

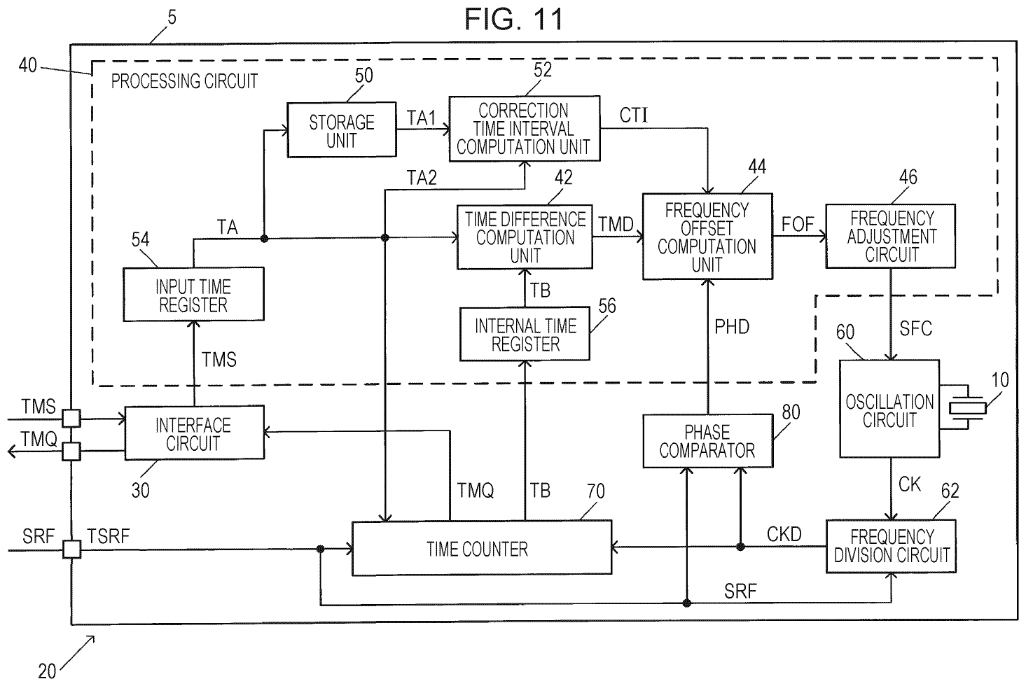

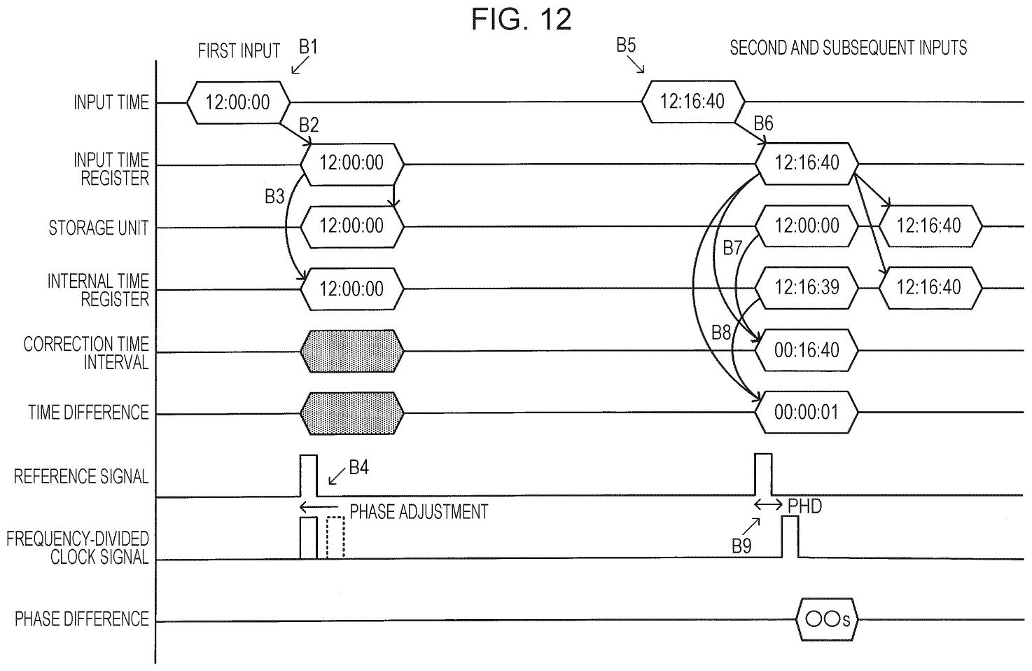

FIG. 11 illustrates another detailed configuration example of the real-time clock device 20 according to the present embodiment. The configuration of FIG. 11 is different from the configuration of FIG. 5 in that the reference signal generation unit 90 of FIG. 5 is not provided in FIG. 11, and instead, the real-time clock device 20 includes a reference signal input terminal TSRF to which the reference signal SRF is input. Other configurations and operations are the same as those in FIG. 5, and thus, a detailed description thereof will be omitted. According to the configuration example of FIG. 11, the reference signal SRF for synchronization of the timestamp information TMS can be input from the outside via the reference signal input terminal TSRF. Then, it is possible to adjust the frequency of the oscillation circuit 60 by calculating the phase difference PHD between the reference signal SRF input from the outside and the frequency-divided clock signal CKD. Furthermore, for example, it is possible to update the internal time of the time counter 70 based on the reference signal SRF input from the outside, and it is possible to update the internal time at an appropriate timing.

FIG. 12 is a signal waveform diagram illustrating an operation of the configuration example of FIG. 11. At the first input indicated by B1 of FIG. 12, the input time TA (TA=TA1=[12:00:00]) is input, and the input time TA (TA=TA1=[12:00:00]) is set in the input time register 54 as indicated by B2. Then, the information regarding the internal time TB of the time counter 70 is updated with the reference signal SRF as a trigger, and the internal time TB (TB=[12:00:00]) is set in the internal time register 56 as indicated by B3. Further, adjustment processing is performed to align the time-counting timing with the timing of the reference signal SRF as indicated by B4. Further, at the second input, the input time TA (TA=TA2=[12:16:40]) is input as indicated by B5. Then, the input time TA (TA=TA2=[12:16:40]) is set in the input time register 54 as indicated by B6. Further, the time difference between the input time TA (TA=TA2=[12:16:40]) and the input time TA (TA=TA1=[12:00:00]) stored in the storage unit 50 is obtained as the correction time interval CTI as indicated by B7. The time difference between the input time TA (TA=TA2=[12:16:40]) and the internal time TB (TB=[12:16:39]) is calculated as indicated by B8, and the phase difference PHD between the reference signal SRF and the frequency-divided clock signal CKD is also calculated as indicated by B9. Then, the frequency offset FOF is calculated based on the time difference TMD and the phase difference PHD, and frequency adjustment of the oscillation circuit 60 is performed based on the frequency offset FOF.

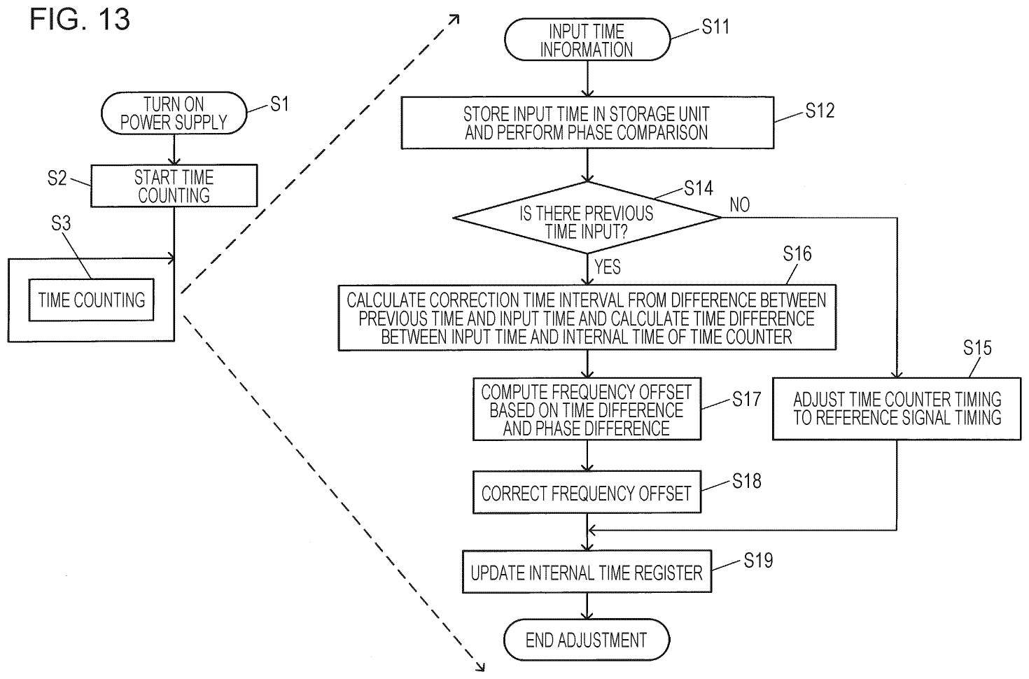

FIG. 13 is a signal waveform diagram illustrating an operation of the configuration example of FIG. 11. FIG. 13 is different from FIG. 7 in that, in FIG. 7, the reference signal generation unit 90 generates the reference signal SRF in step S12, whereas in FIG. 13, such generation of the reference signal SRF is not performed, and the reference signal SRF is input from the outside via the reference signal input terminal TSRF. Then, in step S19 of FIG. 13, the internal time register 56 is updated with the reference signal SRF input from the outside.

In this manner, in the configuration example of FIG. 11, the reference signal input terminal TSRF is provided to input the reference signal SRF from the outside. As a result, an external processing device can instruct a timing of the input time indicated by the timestamp information TMS by using the reference signal SRF and input the reference signal SRF to the real-time clock device 20. Then, the real-time clock device 20 can calculate the phase difference PHD by comparing the phases of the reference signal SRF and the frequency-divided clock signal CKD and adjust the frequency of the oscillation circuit 60 based on the phase difference PHD and the time difference TMD between the input time and the internal time.

As described above, the real-time clock device according to the present embodiment includes the interface circuit to which the timestamp information is input, the oscillation circuit that outputs the oscillation clock signal, the frequency division circuit that divides the frequency of the oscillation clock signal to generate the frequency-divided clock signal, and the time counter that generates the information regarding the internal time based on the frequency-divided clock signal. The real-time clock device further includes the phase comparator that compares the phases of the reference signal for synchronization of the timestamp information and the frequency-divided clock signal, and calculates the phase difference between the reference signal and the frequency-divided clock signal. The real-time clock device further includes the processing circuit that performs processing of updating the information regarding the internal time of the time counter based on the input time indicated by the input timestamp information, and adjusts the frequency of the oscillation circuit based on the time difference between the input time and the internal time and the phase difference.

According to the present embodiment, the information regarding the internal time of the time counter 70 is updated based on the input time indicated by the input timestamp information, so that the internal time can be corrected to the input time. Furthermore, in the present embodiment, the frequency of the oscillation circuit is adjusted based on the time difference between the input time and the internal time and the phase difference between the reference signal and the frequency-divided clock signal. Accordingly, it is possible to adjust the frequency of the oscillation circuit based on the phase difference between the reference signal and the frequency-divided clock signal in addition to the time difference between the input time and the internal time. As a result, it is possible to implement the real-time clock device that can suppress a time counting error caused by an oscillation frequency deviation and provide highly accurate time information even when a deviation occurs in the oscillation frequency due to aging, for example.

Further, in the present embodiment, the processing circuit may include the time difference computation unit that calculates the time difference between the input time and the internal time, the frequency offset computation unit that calculates the frequency offset based on the time difference and the phase difference, and the frequency adjustment circuit that adjusts the frequency of the oscillation circuit based on the frequency offset.

As a result, it is possible to adjust the frequency of the oscillation circuit by calculating the frequency offset that also reflects the phase difference between the reference signal and the frequency-divided clock signal in addition to the time difference between the input time indicated by the timestamp information and the internal time set in the time counter.

In the present embodiment, the processing circuit may calculate the correction time interval based on the first input time indicated by the timestamp information that is input at the first timing, and the second input time indicated by the timestamp information that is input at the second timing after the first timing, and adjust the frequency of the oscillation circuit based on the correction time interval, the time difference, and the phase difference.

As a result, it is possible to implement, even when the correction interval based on the timestamp information is not constant, appropriate frequency adjustment of the oscillation circuit based on the time difference and the phase difference by calculating the correction time interval based on the difference between the first input time at the first timing and the second input time at the second timing.

In the present embodiment, the processing circuit may include the storage unit that stores the first input time, and the correction time interval computation unit that calculates the correction time interval based on the first input time stored in the storage unit and the second input time indicated by the timestamp information at the second timing. The processing circuit may further include the time difference computation unit that calculates the time difference between the second input time and the internal time, the frequency offset computation unit that calculates the frequency offset based on the correction time interval, the time difference, and the phase difference, and the frequency adjustment circuit that adjusts the frequency of the oscillation circuit based on the frequency offset.

As a result, even when the correction interval based on the timestamp information is not constant, the correction time interval computation unit calculates the correction time interval based on the first input time and the second input time, so that it is possible to implement appropriate frequency adjustment of the oscillation circuit based on the time difference and phase difference.

In the present embodiment, the real-time clock device may further include the reference signal generation unit that generates the reference signal based on the timestamp information.

As a result, the reference signal can be generated based on the timestamp information without inputting the reference signal from the outside, so that it is possible to adjust the frequency of the oscillation circuit by calculating the phase difference between the reference signal and the frequency-divided clock signal.

In the present embodiment, the reference signal generation unit may generate the reference signal based on the input timing or the input end timing of the timestamp information.

As a result, the timing of the reference signal can be set by effectively utilizing the input timing or the input end timing of the timestamp information.

In the present embodiment, the real-time clock device may further include the reference signal input terminal to which the reference signal is input.

As a result, the reference signal for synchronization of the timestamp information can be input from the outside via the reference signal input terminal, so that it is possible to adjust the frequency of the oscillation circuit by calculating the phase difference between the reference signal input from the outside and the frequency-divided clock signal.

Although the present embodiment has been described in detail as above, those skilled in the art will easily understand that many modifications can be made without substantively departing from the novelty and effects of the present disclosure. Therefore, all such modifications are intended to be included within the scope of the present disclosure. For example, a term that appears at least once in the specification or drawings together with a different term with a broader or synonymous meaning may be replaced by that different term anywhere in the specification or drawings. Further, all combinations of the present embodiment and modifications also fall within the scope of the present disclosure. Further, the configuration, operation, and the like of the real-time clock device are not limited to those described in the present embodiment, and various modifications are possible.

What is claimed is:

1. A real-time clock device comprising:
an interface circuit that receives timestamp information;
an oscillation circuit that outputs an oscillation clock signal;
a frequency division circuit that divides a frequency of the oscillation clock signal to generate a frequency-divided clock signal;
a time counter that generates information regarding an internal time based on the frequency-divided clock signal;
a phase comparator that compares phases of a reference signal and the frequency-divided clock signal and calculates a phase difference between the reference signal and the frequency-divided clock signal; and
a processing circuit that performs processing of updating the information regarding the internal time of the time counter based on an input time indicated by the input timestamp information, and adjusts a frequency of the oscillation circuit based on a time difference between the input time and the internal time and the phase difference.

2. The real-time clock device according to claim 1, wherein
the processing circuit includes:
a time difference computation unit that calculates the time difference between the input time and the internal time;
a frequency offset computation unit that calculates a frequency offset based on the time difference and the phase difference; and
a frequency adjustment circuit that adjusts the frequency of the oscillation circuit based on the frequency offset.

3. The real-time clock device according to claim 1, wherein
the processing circuit calculates a correction time interval based on a first input time indicated by the timestamp information that is input at a first timing, and a second input time indicated by the timestamp information that is input at a second timing after the first timing, and adjusts the frequency of the oscillation circuit based on the correction time interval, the time difference, and the phase difference.

4. The real-time clock device according to claim 3, wherein
the processing circuit includes:
a storage unit that stores the first input time;
a correction time interval computation unit that calculates the correction time interval based on the first input time stored in the storage unit and the second input time indicated by the timestamp information at the second timing;
a time difference computation unit that calculates the time difference between the second input time and the internal time;
a frequency offset computation unit that calculates a frequency offset based on the correction time interval, the time difference, and the phase difference; and
a frequency adjustment circuit that adjusts the frequency of the oscillation circuit based on the frequency offset.

5. The real-time clock device according to claim 1, further comprising a reference signal generation unit that generates the reference signal based on the timestamp information.

6. The real-time clock device according to claim 5, wherein
the reference signal generation unit generates the reference signal based on an input timing or an input end timing of the timestamp information.

7. The real-time clock device according to claim 1, further comprising a reference signal input terminal to which the reference signal is input.
